(19) United States
(12) Patent Application Publication
(10) Pub. No.: US 2015/0009460 A1
(43) Pub. Date: Jan. 8, 2015

(54) ARRAY SUBSTRATE AND LIQUID CRYSTAL DISPLAY PANEL HAVING THE SAME

(71) Applicant: Samsung Display Co., Ltd., Yongin-City (KR)

(72) Inventors: Dae-Hwan JANG, Gwangmyeong-si (KR); Dae-Young LEE, Seoul (KR); Jung-Gun NAM, Seoul (KR); Gug-Rae JO, Asan-si (KR)

(73) Assignee: Samsung Display Co., Ltd., Yongin-City (KR)

(21) Appl. No.: 14/107,167

(22) Filed: Dec. 16, 2013

(30) Foreign Application Priority Data
Jul. 4, 2013 (KR) 10-2013-0078283

(51) Int. Cl. G02F 1/1362; H01L 27/12

(52) U.S. Cl. CPC G02F 1/136209; H01L 27/1214
USPC 349/106; 257/72; 349/113; 349/110

(57) ABSTRACT

An array substrate includes a reflecting pattern, a protecting pattern, a first passivation layer and a thin film transistor. The reflecting pattern is on a substrate. The protecting pattern is on the reflecting pattern and overlaps the reflecting pattern. The first passivation layer covers the substrate and the protecting pattern. The thin film transistor is on the first passivation layer and overlaps the reflecting pattern. The first passivation layer includes a silicon oxycarbide (SiOC).

This application claims priority to Korean Patent Application No. 10-2013-0078283, filed on Jul. 4, 2013, and all the benefits accruing therefrom under 35 U.S.C. §119, the contents of which are herein incorporated by reference in their entireties.

### BACKGROUND

1. Field

Exemplary embodiments of the invention relate to an array substrate and a liquid crystal display panel including the array substrate. More particularly, exemplary embodiments of the invention relate to an array substrate increasing a luminance of an image and a liquid crystal display panel including the array substrate.

2. Description of the Related Art

Generally, a liquid crystal display (“LCD”) apparatus includes an array substrate and an opposite substrate. According to an arrangement of a liquid crystal, a transmittance of a light passing through the liquid crystal is adjusted so that a desired image may be displayed. The liquid crystal display apparatus includes a display panel and a light source to provide the light to the display panel. A backlight assembly of the liquid crystal apparatus may include the light source. The light emitted from the light source is provided to the display panel including the array substrate and the opposite substrate.

A resolution of the display panel and a degree of integration of a pixel have been increased to improve a display quality of the display panel. For example, 500 pixels are integrated in an inch so that the display panel may display an image having a resolution of 4096×3072.

### SUMMARY

Exemplary embodiments of the invention provide an array substrate to increase a luminance of an image in a liquid crystal display panel having a high degree of integration of a pixel without increasing the number of light sources. Exemplary embodiments of the invention also provide a liquid crystal display panel including the array substrate.

In an exemplary embodiment of an array substrate according to the invention, the array substrate includes a reflecting pattern, a protecting pattern, a first passivation layer and a thin film transistor. The reflecting pattern is on a substrate. The protecting pattern is on the reflecting pattern and overlaps the reflecting pattern. The first passivation layer covers the substrate and the protecting pattern. The thin film transistor is on the first passivation layer and overlaps the reflecting pattern. The first passivation layer includes silicon oxycarbide (SiOC).

In an exemplary embodiment, the array substrate may further include a second passivation layer between the first passivation layer and the thin film transistor. The second passivation layer may include inorganic silicon.

In an exemplary embodiment, the inorganic silicon may include silicon oxide (SiOx) or silicon nitride (SiNx).

In an exemplary embodiment, a thickness of the first passivation layer may be equal to or greater than about 1 micrometer (μm).

In an exemplary embodiment, the reflecting pattern may include aluminum (Al), gold (Au), silver (Ag), copper (Cu), chromium (Cr), iron (Fe), nickel (Ni) or an alloy thereof.

In an exemplary embodiment, the protecting pattern may include titanium (Ti).

In an exemplary embodiment, the thin film transistor may include a gate electrode, a semiconductor pattern overlapping the gate electrode, a source electrode overlapping a first end portion of the semiconductor pattern, and a drain electrode spaced apart from the source electrode and overlapping a second end portion of the semiconductor pattern.

In an exemplary embodiment, a boundary portion of the thin film transistor may correspond to a boundary portion of the reflecting pattern.

In an exemplary embodiment, the array substrate may further include a color filter pattern on the substrate on which the thin film transistor is formed.

In an exemplary embodiment, the array substrate may further include an organic insulating layer on the thin film transistor and a pixel electrode on the organic insulating layer.

In an exemplary embodiment of a liquid crystal display panel according to the invention, the liquid crystal display panel includes an array substrate, an opposite substrate and a liquid crystal layer. The array substrate includes a thin film transistor. The opposite substrate faces the array substrate. The liquid crystal layer is between the array substrate and the opposite substrate. The array substrate further includes a reflecting pattern on a base substrate and overlapping the thin film transistor, a protecting pattern on the reflecting pattern and overlapping the reflecting pattern and a first passivation layer covering the base substrate and the reflecting pattern. The thin film transistor is on the first passivation layer. The first passivation layer includes silicon oxycarbide (SiOC).

In an exemplary embodiment, the array substrate may further include a second passivation layer between the first passivation layer and the thin film transistor. The second passivation layer may include inorganic silicon.

In an exemplary embodiment, the inorganic silicon may include silicon oxide (SiOx) or silicon nitride (SiNx).

In an exemplary embodiment, the reflecting pattern may include aluminum (Al), gold (Au), silver (Ag), copper (Cu), chromium (Cr), iron (Fe), nickel (Ni) or an alloy thereof

In an exemplary embodiment, the protecting pattern may include titanium (Ti).

In an exemplary embodiment, the opposite substrate may include a light blocking pattern corresponding to the reflecting pattern.

In an exemplary embodiment, the opposite substrate may further include a color filter pattern on the light blocking pattern.

In an exemplary embodiment, the opposite substrate may further include a common electrode on the light blocking pattern.

In an exemplary embodiment, the array substrate may further include a color filter pattern on the thin film transistor.

In an exemplary embodiment, a thickness of the first passivation layer may be greater than a thickness of the reflecting pattern.

According to one or more exemplary embodiment of the array substrate and the liquid crystal display panel including the array substrate, the array substrate includes a reflecting pattern reflecting light from a backlight unit in a non-opening portion of the liquid crystal display panel which blocks light transmitted from the backlight, so that the light from the backlight unit emitted to the non-opening portion may be reused. Thus, a luminance of an image may be increased.

In addition, the array substrate further includes a passivation layer at a specific thickness and covering the reflecting pattern so that an undesirable electric effect to a thin film transistor by the reflecting pattern may be decreased.

### BRIEF DESCRIPTION OF THE DRAWINGS

The above and other features and advantages of the invention will become more apparent by describing in detailed exemplary embodiments thereof with reference to the accompanying drawings, in which:

FIG. 1 is a cross-sectional view illustrating an exemplary embodiment of a liquid crystal display apparatus according to the invention;

FIG. 2 is a cross-sectional view illustrating an exemplary embodiment of a reused light in the liquid crystal display apparatus of FIG. 1;

FIGS. 3A to 3H are cross-sectional views illustrating an exemplary embodiment of a method of manufacturing an array substrate of the liquid crystal display apparatus of FIG. 1; and

FIG. 4 is a cross-sectional view illustrating another exemplary embodiment of a liquid crystal display apparatus according to the invention.

### DETAILED DESCRIPTION

When a degree of integration of pixels in a display panel of a display device increases to improve a display, a total area of a boundary portion between pixels, which block the light from the backlight unit, may also increase. Thus, a transmittance of the light provided from a backlight unit of the display device may decrease. In addition, when a number of light sources in the backlight unit increases to improve a luminance of the backlight assembly, a manufacturing cost of the liquid crystal display apparatus may increase. Therefore, there remains a need for an improved display device having high resolution with a high degree of integration of pixels, a minimal total boundary area between the pixels and increased transmittance of light.

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” or “coupled to” another element or layer, the element or layer can be directly on or connected to another element or layer or intervening elements or layers. In contrast, when an element is referred to as being “directly on” or “directly connected to” another element or layer, there are no intervening elements or layers present. As used herein, connected may refer to elements being physically and/or electrically connected to each other. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “lower,” “under,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” or “under” relative to other elements or features would then be oriented “above” relative to the other elements or features. Thus, the exemplary term “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be explained in detail with reference to the accompanying drawings.

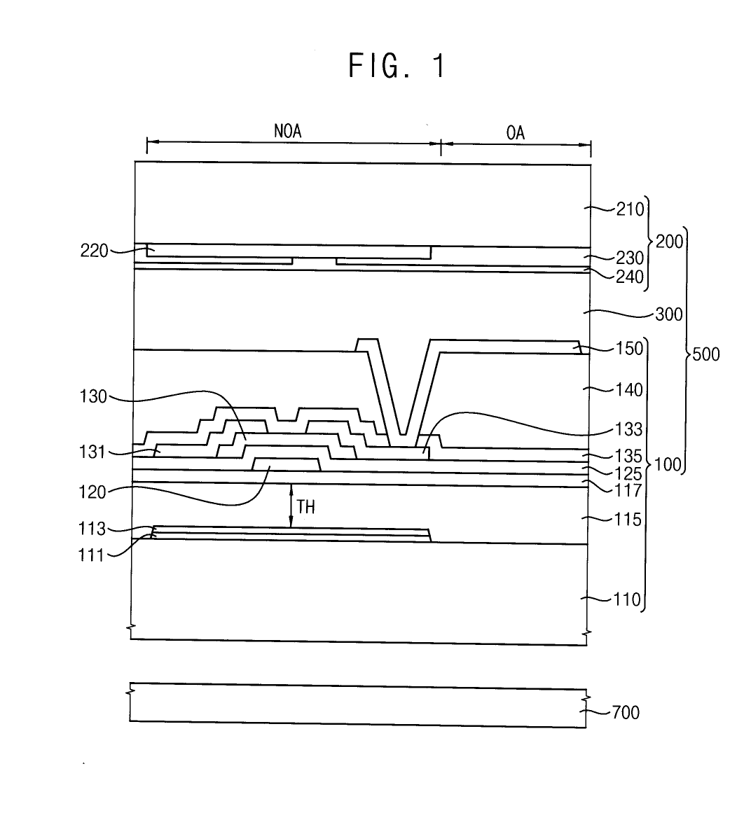

FIG. 1 is a cross-sectional view illustrating an exemplary embodiment of a liquid crystal display apparatus according to the invention.

Referring to FIG. 1, the liquid crystal display apparatus includes a liquid crystal display panel 500 and a backlight unit 700. The liquid crystal display panel 500 includes an array substrate 100, an opposite substrate 200 and a liquid crystal layer 300. An opening portion OA is defined in the liquid crystal display panel 500, and through which a light from the backlight unit 700 passes. A non-opening portion NOA of the liquid crystal display panel 500 blocks the light. The opening portion OA may correspond to a plurality of pixel areas (not shown) disposed in a matrix form within the liquid crystal display apparatus. The non-opening portion OA may correspond to boundary portions between the pixel areas.

The array substrate 100 includes a thin film transistor and a pixel electrode 150 electrically connected to the thin film transistor. The opposite substrate 200 faces the array substrate 100. The liquid crystal layer 300 is disposed between the array substrate 100 and the opposite substrate 200.

Although, the array substrate 100 is disposed under the liquid crystal layer 300 and the backlight unit 700 emits the light to the array substrate 100 in the illustrated exemplary embodiment, the invention is not limited thereto. Alternatively, the array substrate 100 may be disposed on (e.g., above) the liquid crystal layer 300, the opposite substrate 200 may be disposed under the liquid crystal layer 300 and the backlight unit 700 may emit the light to the opposite substrate 200.

The array substrate 100 includes a first base substrate 110, a reflecting pattern 111, a protecting pattern 113, a passivation layer member, the thin film transistor, a gate insulating layer 125, an inorganic insulating layer 135, an organic insulating layer 140 and the pixel electrode 150. The thin film transistor corresponds to the non-opening portion NOA. The thin film transistor includes a gate electrode 120, a semiconductor pattern 130, a source electrode 131 and a drain electrode 133.

The first base substrate 110 includes a transparent and insulating material. In one exemplary embodiment, for example, the first base substrate 110 may include a glass, a quartz, a plastic, a polyethylene terephthalate resin, a polyethylene resin or a polycarbonate resin.

The reflecting pattern 111 corresponds to the non-opening portion NOA. The reflecting pattern 111 is disposed on the first base substrate 110. The reflecting pattern 111 may include a metal having a relatively high reflectance. In one exemplary embodiment, for example, the reflecting pattern includes aluminum (Al), gold (Au), silver (Ag), copper (Cu), chromium (Cr), iron (Fe), nickel (Ni) or an alloy thereof.

The protecting pattern 113 is disposed on the reflecting pattern 111. The protecting pattern 113 overlaps the reflecting pattern 111. In one exemplary embodiment, for example, the protecting pattern 113 may include titanium (Ti). Thus, damage to the reflecting pattern 111 due to a high temperature and/or a high pressure in a process manufacturing the liquid crystal display apparatus, may be reduced or effectively prevented by the protecting pattern 113.

The passivation layer member may include a multiple layer structure including at least two layers. As shown in FIG. 1, for example, the passivation layer may include a first passivation layer 115, and a second passivation layer 117 disposed on the first passivation layer 115.

The first passivation layer 115 is disposed on the protecting pattern 113 and the first base substrate 110. The first passivation layer 115 totally covers the opening portion OA and the non-opening portion NOA. In one exemplary embodiment, for example, the first passivation layer 115 may include silicon oxycarbide (SiOC). A cross-sectional thickness TH of the first passivation layer 115 is defined with reference from the protecting pattern 113. The cross-sectional thickness TH of the first passivation layer 115 may be greater than a cross-sectional thickness of the reflecting pattern 111. The cross-sectional thickness of the reflecting pattern 111 may be defined with reference to the first base substrate 110. In one exemplary embodiment, for example, the cross-sectional thickness TH of the first passivation layer 115 may be equal to or greater than about 1 micrometer (μm) and equal to or less than about 10 μm. The cross-sectional thickness TH of the first passivation layer 115 may be set not to form an undesirable capacitance between the thin film transistor and the reflecting pattern 111.

The second passivation layer 117 is disposed on the first passivation layer 115. In one exemplary embodiment, for example, the second passivation layer 117 may include an inorganic silicon. In one exemplary embodiment, for example, the second passivation layer 117 may include a silicon oxide (SiOx) or a silicon nitride (SiNx). In one exemplary embodiment, for example, the second passivation layer 117 may include a silicon oxynitride (SiON). The first passivation layer 115 and/or the second passivation layer 117 planarizes the first base substrate 110 so that a flat upper surface is provided. Thus, owing to the flat upper surface of the second passivation layer 117, the gate electrode 120 and/or the semiconductor pattern 130 have sufficient adhesion to the second passivation layer 117.

The gate electrode 120 corresponds to the non-opening portion NOA. The gate electrode 120 is disposed on the second passivation layer 117. The gate electrode 120 overlaps the reflecting pattern 111. The gate electrode 120 is physically and/or electrically connected to a gate line (not shown). A gate signal to drive the thin film transistor from a gate driver (not shown) is applied to the gate electrode 120 via the gate line. The gate electrode 120 may include a copper (Cu) or a copper oxide (CuOx). Alternatively, the gate electrode 120 may include a gallium doped zinc oxide (“GZO”), an indium doped zinc oxide (“IZO”) or an alloy of a copper (Cu) and a manganese (Mn).

The gate insulating layer 125 is disposed on the gate electrode 120 and the second passivation layer 117. The gate insulating layer 125 may include a transparent and insulating material. In one exemplary embodiment, for example, the gate insulating layer 125 may include a silicon oxide (SiOx) or a silicon nitride (SiNx).

The semiconductor pattern 130 is disposed on the gate insulating layer 125. The semiconductor pattern 130 overlaps the gate electrode 120 and the reflecting pattern 111. The semiconductor pattern 130 may include an indium (In), a zinc (Zn), a gallium (Ga), a tin (Sn) or a hafnium (HO. In one exemplary embodiment, for example, the semiconductor pattern 130 may include an oxide semiconductor such as an indium gallium zinc oxide (“IGZO”), an indium tin zinc oxide (“ITZO”) or a hafnium indium zinc oxide (“HIZO”).

The source electrode 131 is disposed on the gate insulating layer 125. The source electrode 131 overlaps a first end portion of the semiconductor pattern 130. The drain electrode 133 is spaced apart from the source electrode 131. The drain electrode 133 is disposed on the gate insulating layer 125. The drain electrode 133 overlaps a second end portion of the semiconductor pattern 130 opposite to the first end portion. Although, the thin film transistor has a bottom gate structure which includes the gate electrode disposed under the semiconductor pattern in the illustrated exemplary embodiment, the invention is not limited thereto. Alternatively, the thin film transistor may have a top gate structure which includes the gate electrode disposed on (e.g., above) the semiconductor pattern. In an exemplary embodiment, a boundary portion of the thin film transistor may correspond to the boundary portion of the reflecting pattern 113. The boundary portion may be defined with reference to the outer edge of the element, such as in a plan view.

The inorganic insulating layer 135 is disposed on the source electrode 131, the drain electrode 133 and the first base substrate 110. The inorganic insulating layer 135 may include a same material as a material of the gate insulating layer 125.

The organic insulating layer 140 is disposed on the thin film transistor and the first base substrate 110. The organic insulating layer 140 may include a substantially flat upper surface. The organic insulating layer 140 may include an organic and insulating material such as an acrylic resin or a phenol resin.

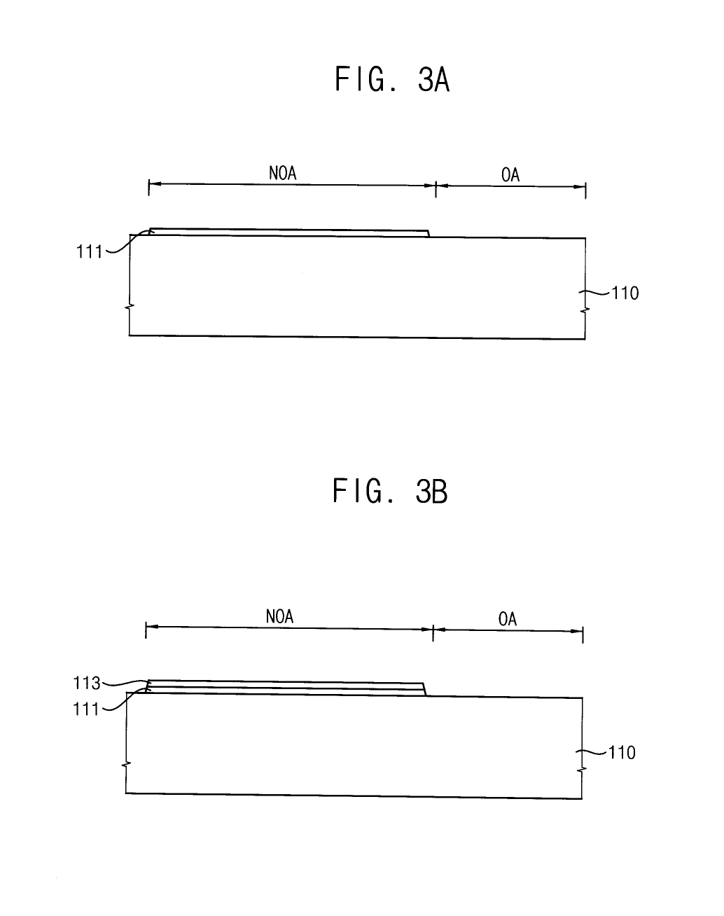

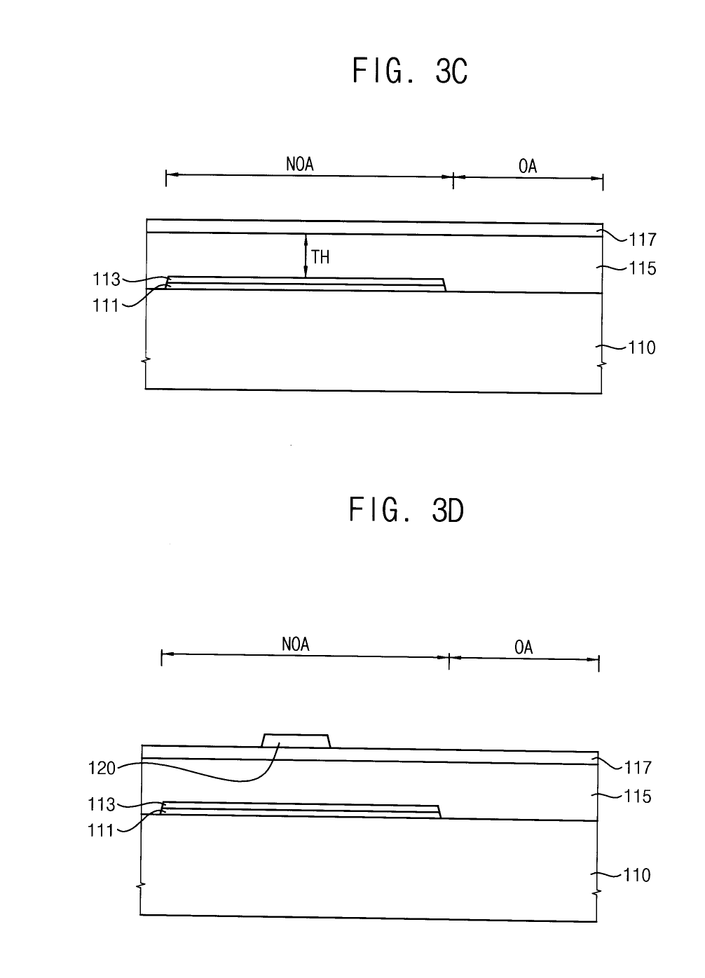

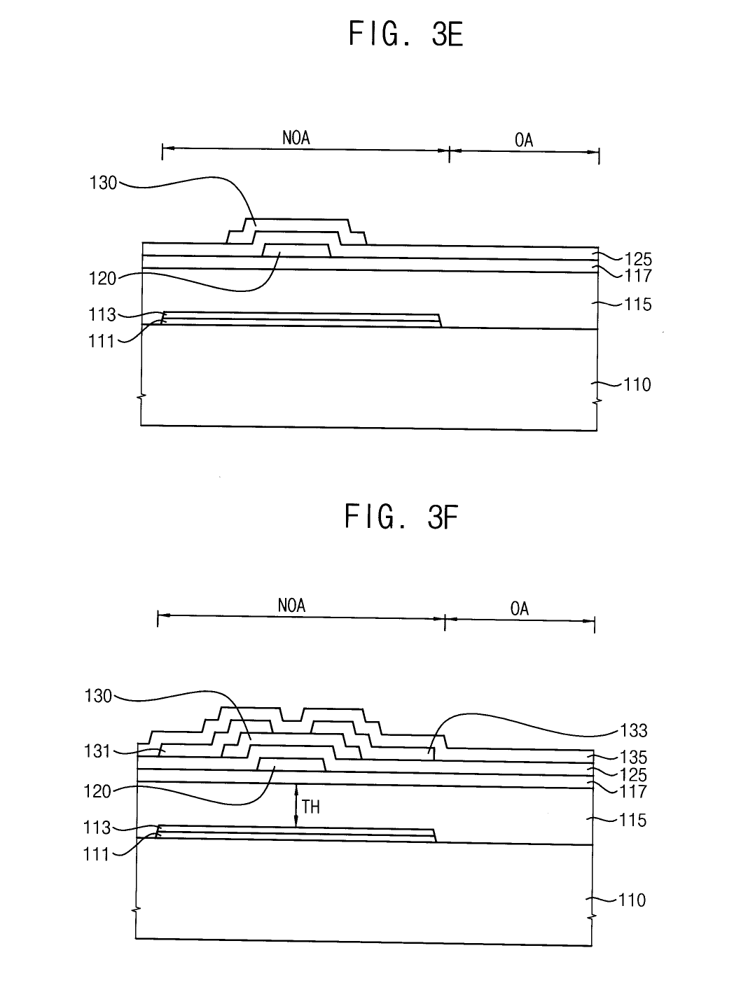

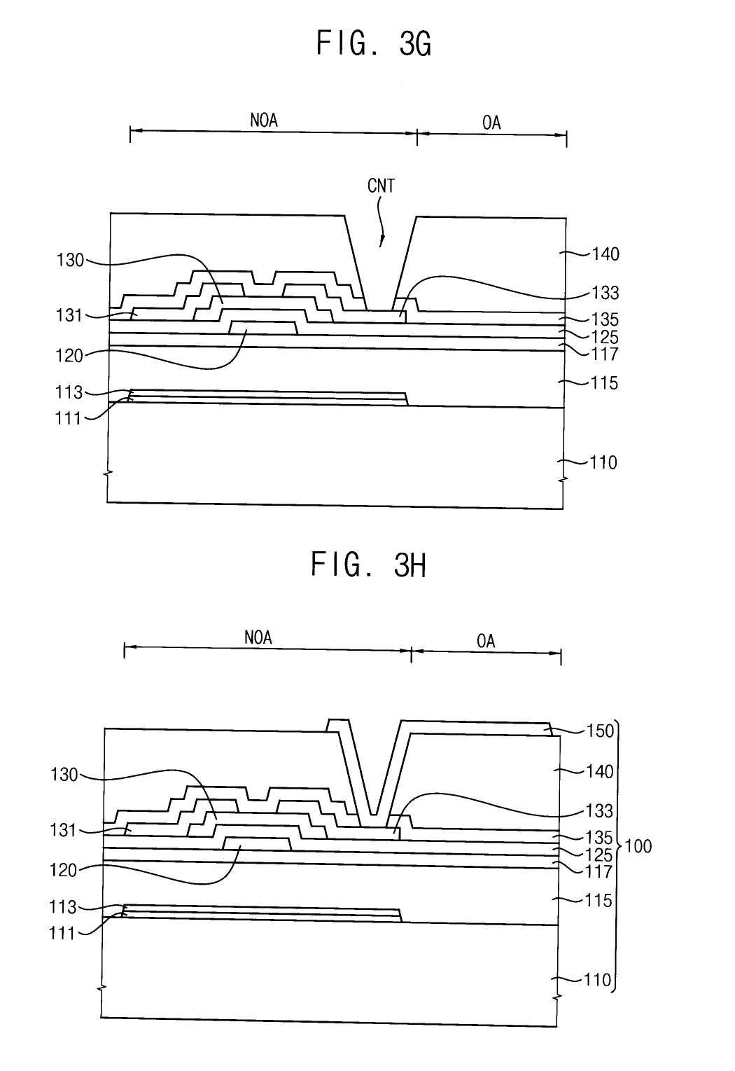

A contact hole CNT (see FIG. 3G) is defined in the organic insulation layer 140 and the inorganic insulating layer 135. The pixel electrode 150 overlaps the opening portion OA. The pixel electrode 150 is physically and/or electrically connected to the drain electrode 133 through the contact hole CNT passing through the organic insulating layer 140 and the inorganic insulating layer 135. An end portion of the pixel electrode 150 partially overlaps the non-opening portion NOA. The pixel electrode 150 includes a transparent and conductive material. In one exemplary embodiment, for example, the pixel electrode 150 includes IZO, a tin oxide (SnOx) or a zinc oxide (ZnOx).

The opposite substrate 200 includes a second base substrate 210, a light blocking pattern 220, a color filter pattern 230 and a common electrode 240.

The second base substrate 210 includes a transparent insulating material. The second base substrate 210 may include a substantially same material as a material of the first base substrate 110. In one exemplary embodiment, for example, the second base substrate 210 may include a glass, a quartz, a plastic, a polyethylene terephthalate resin, a polyethylene resin or a polycarbonate resin.

The light blocking pattern 220 corresponds to the non-opening portion NOA. The light blocking pattern 220 is disposed on the second base substrate 210. The light blocking pattern 220 blocks the light at the boundary portion of the pixel areas. In one exemplary embodiment, for example, the light blocking pattern 220 may overlap a data line, a gate line and/or the thin film transistor. In an exemplary embodiment, a boundary line of the light blocking pattern 220 may be substantially the same as a boundary line of the reflecting pattern 111. That is, edges of the light blocking pattern 220 and the reflecting pattern 111 may coincide with each other.

The color filter pattern 230 corresponds to the opening portion OA. The color filter pattern 230 is disposed on the light blocking pattern 220 and the second base substrate 210. The color filter pattern 230 may partially overlap the light blocking pattern 220. The color filter pattern 230 may include on or more color filter. In one exemplary embodiment, for example, the color filter pattern 230 may include a red filter, a green filter and a blue filter.

The common electrode 240 is disposed on the color filter pattern 230 and the light blocking pattern 220. The common electrode 240 includes a transparent and conductive material. For example, the common electrode 240 may include IZO, an indium tin oxide (“ITO”), SnOx or ZnOx.

The backlight unit 700 is disposed under the liquid crystal display panel 500. The backlight unit 700 provides the light to the array substrate 100.

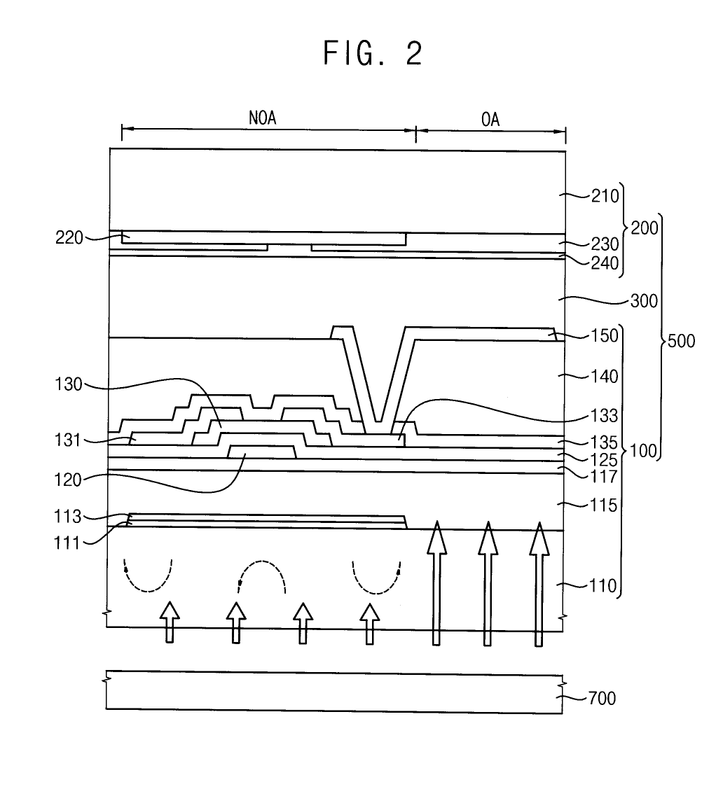

FIG. 2 is a cross-sectional view illustrating an exemplary embodiment of a reused light in the liquid crystal display apparatus of FIG. 1.

Referring to FIG. 2, the light emitted from the backlight unit 700 passes through the first base substrate 110 and is provided to the reflecting pattern 111. The reflecting pattern 111 reflects the light emitted from the backlight unit 700 toward a lower direction.

The light reflected by the reflecting pattern 111 toward the lower direction may be reflected by the first base substrate 110 and/or the backlight unit 700 toward an upper direction opposite to the lower direction, and be ultimately provided again to the liquid crystal display panel 500.

According to the array substrate 100 and the liquid crystal display panel 500 of the illustrated exemplary embodiment, the light emitted from the backlight unit 700 is reflected by the reflecting pattern 111 repeatedly so that an efficiency of the light may be improved. In addition, the reflecting pattern 111 is spaced apart from the thin film transistor by the first passivation layer 115 so that an undesirable electric effect to the thin film transistor by the reflecting pattern 111 may be decreased.

FIGS. 3A to 3H are cross-sectional views illustrating an exemplary embodiment of a method of manufacturing an array substrate of the liquid crystal display apparatus of FIG. 1.

Referring to FIG. 3A, a reflecting material layer is formed (e.g., provided) on the first base substrate 110. The reflecting material layer is patterned to form the reflecting pattern 111. The reflecting pattern 111 may correspond to the non-opening portion NOA. The non-opening portion NOA defines the opening portion OA. In one exemplary embodiment, for example, the reflecting pattern 111 pattern may include a metal having a relatively high reflectance. In one exemplary embodiment, for example, the reflecting pattern 111 may include aluminum (Al), gold (Au), silver (Ag), copper (Cu), chromium (Cr), iron (Fe), nickel (Ni) or an alloy thereof.

Referring to FIG. 3B, a protecting material metal layer is formed on the reflecting pattern 111 and the first base substrate 110. The protecting metal layer is patterned to form the protecting pattern 113. The protecting pattern 113 overlaps the reflecting pattern 111. In one exemplary embodiment, for example, the protecting pattern 113 may include a metal such as titanium (Ti). Damage to the reflecting pattern 111 due to a high temperature and/or a high pressure in a process manufacturing the liquid crystal display apparatus, may be reduced or effectively prevented by the protecting pattern 113.

Referring to FIG. 3C, the passivation layer member is formed on the protecting pattern 113 and the first base substrate 110. The passivation layer member may include a multiple layer structure including at least two layers. In one exemplary embodiment, for example, the passivation layer may include the first passivation layer 115, and the second passivation layer 117 disposed on the first passivation layer 115. The first passivation layer 115 is formed on the protecting pattern 113 and the first base substrate 110. The first passivation layer 115 totally covers the opening portion OA and the non-opening portion NOA. In one exemplary embodiment, for example, the first passivation layer 115 may include silicon oxycarbide (SiOC).

The first passivation layer 115 has a cross-sectional thickness TH with reference to the protecting pattern 113. The cross-sectional thickness TH of the first passivation layer 115 may be greater than a cross-sectional thickness of the reflecting pattern 111. In one exemplary embodiment, for example, the cross-sectional thickness TH of the first passivation layer 115 may be equal to or greater than about 1 μm and equal to or less than about 10 μm. The cross-sectional thickness TH of the first passivation layer 115 may be set not to form an undesirable capacitance between the thin film transistor and the reflecting pattern 111.

The second passivation layer 117 is formed on the first passivation layer 115. The second passivation layer 117 may include a silicon oxide (SiOx) or a silicon nitride (SiNx). In one exemplary embodiment, for example, the second passivation layer 117 may include a silicon oxynitride (SiON). The second passivation layer 117 planarizes the first base substrate 110 so that the second passivation layer 117 provides a flat upper surface. Thus, the gate electrode 120 or the semiconductor pattern 130 may have good adhesion with the upper surface of the second passivation layer 117.

Referring to FIG. 3D, a gate material layer is formed on the second passivation layer 117. The gate material layer is patterned to form the gate electrode 120. The gate electrode 120 may include a metal such as a copper (Cu) or a copper oxide (CuOx). Alternatively, the gate electrode 120 may include GZO, IZO or an alloy of a copper (Cu) and a manganese (Mn).

Referring to FIG. 3E, the gate insulating layer 125 is formed on the gate electrode 120 and the second passivation layer 117. The gate insulating layer 125 may include an inorganic insulating material such as a silicon oxide (SiOx) or a silicon nitride (SiNx) or a transparent and organic material. The gate insulating layer 125 may formed by a chemical vapor deposition (“CVD”) process or an organic layer coating process.

The semiconductor pattern 130 is formed on the gate insulating layer 125. The semiconductor pattern 130 overlaps the gate electrode 120 and the reflecting pattern 111. The semiconductor pattern 130 may include an indium (In), a zinc (Zn), a gallium (Ga), a tin (Sn) or a hafnium (Hf). In one exemplary embodiment, for example, the semiconductor pattern 130 may include an oxide semiconductor such as IGZO, ITZO or HIZO.

Referring to FIG. 3F, the source electrode 131 and the drain electrode 133 are formed on the semiconductor pattern 130 and the gate insulating layer 125. The inorganic insulating layer 135 is formed on the source electrode 131, the drain electrode 133 and the first base substrate 110. The inorganic insulating layer 135 covers the source electrode 131 and the drain electrode 133. The source electrode 131 and the drain electrode 133 may be formed from a same material and in a same layer. In one exemplary embodiment, for example, a signal material layer may be formed on the semiconductor pattern 130 and the gate insulating layer 125. The signal material layer may be etched to form the source electrode 131 and the drain electrode 133. The signal material layer may include a multiple layer structure including a plurality of metal layers. In one exemplary embodiment, for example, the signal material layer may include aluminum (Al), titanium (Ti), copper (Cu), molybdenum (Mo), tantalum (Ta), tungsten (W), neodymium (Nd), chromium (Cr) or silver (Ag).

Referring to FIG. 3G the organic insulating layer 140 is formed on the inorganic insulating layer 135. The contact hole CNT exposing a portion of the drain electrode 133 is formed through the organic insulating layer 140 and the inorganic insulating layer 135. The organic insulating layer 140 may have a substantially flat upper surface. The organic insulating layer 140 may include an organic and insulating material such as an acrylic resin or a phenol resin.

Referring to FIG. 3H, the pixel electrode 150 is formed on the organic insulating layer 140. The pixel electrode 150 makes contact to the drain electrode 133 through the contact hole CNT. The pixel electrode 150 may include a transparent and conductive material. For example, the pixel electrode 150 may include IZO, a tin oxide (SnOx) or a zinc oxide (ZnOx).

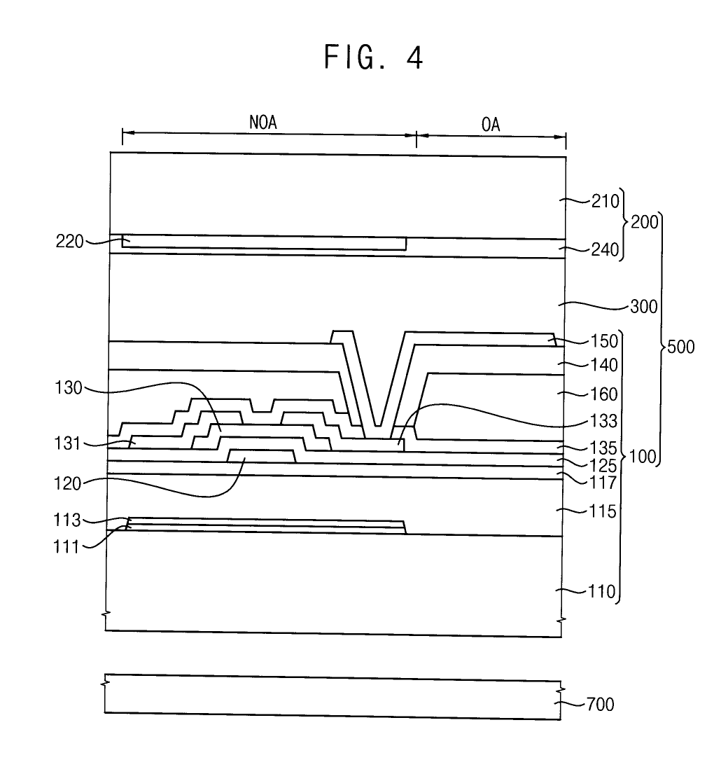

FIG. 4 is a cross-sectional view illustrating another exemplary embodiment of a liquid crystal display apparatus according to an exemplary embodiment of the invention.

Referring to FIG. 4, the liquid crystal display apparatus includes a liquid crystal display panel 500 and a backlight unit 700. The liquid crystal display panel 500 includes an array substrate 100, an opposite substrate 200 and a liquid crystal layer 300. An opening portion OA is defined in the liquid crystal display panel 500 and through which a light from the backlight unit 700 passes. A non-opening portion NOA of the liquid crystal display panel 500 blocks the light. The liquid crystal display apparatus of the illustrated exemplary embodiment is substantially the same as the liquid crystal display apparatus of the previous exemplary embodiment explained referring to FIG. 1 except that the array substrate 100 includes a color filter pattern 160. Thus, the same reference numerals will be used to refer to the same or like parts as those described in the previous exemplary embodiment of FIG. 1 and any repetitive explanation concerning the above elements will be omitted or simplified.

The array substrate 100 includes a first base substrate 110, a reflecting pattern 111, a protecting pattern 113, a passivation layer member, a thin film transistor, a gate insulating layer 125, an inorganic insulating layer 135, the color filter pattern 160, an organic insulating layer 140 and a pixel electrode 150. The thin film transistor corresponds to the non-opening portion NOA. The thin film transistor includes a gate electrode 120, a semiconductor pattern 130, a source electrode 131 and a drain electrode 133.

The first base substrate 110 includes a transparent and insulating material.

The reflecting pattern 111 corresponds to the non-opening portion NOA. The reflecting pattern 111 is disposed on the first base substrate 110. The reflecting pattern 111 may include a metal having a relatively high reflectance. In one exemplary embodiment, for example, the reflecting pattern includes aluminum (Al), gold (Au), silver (Ag), copper (Cu), chromium (Cr), iron (Fe), nickel (Ni) or an alloy thereof.

The protecting pattern 113 is disposed on the reflecting pattern 111. The protecting pattern 113 overlaps the reflecting pattern 111. In one exemplary embodiment, for example, the protecting pattern 113 may include titanium (Ti).

The passivation layer member may include a multiple layer structure including at least two layers. As illustrated in FIG. 4, for example, the passivation layer member may include a first passivation layer 115, and a second passivation layer 117 disposed on the first passivation layer 115.

The first passivation layer 115 is disposed on the protecting pattern 113 and the first base substrate 110. The first passivation layer 115 totally covers the opening portion OA and the non-opening portion NOA. In one exemplary embodiment, for example, the first passivation layer 115 may include silicon oxycarbide (SiOC). A cross-sectional thickness of the first passivation layer 115 may be set not to form an undesirable capacitance between the thin film transistor and the reflecting pattern 111.

The second passivation layer 117 is disposed on the first passivation layer 115. In one exemplary embodiment, for example, the second passivation layer 117 may include an inorganic silicon. In one exemplary embodiment, for example, the second passivation layer 117 may include a silicon oxide (SiOx) or a silicon nitride (SiNx).

The gate electrode 120 corresponds to the non-opening portion NOA. The gate electrode 120 is disposed on the second passivation layer 117. The gate electrode 120 overlaps the reflecting pattern 111.

The gate insulating layer 125 is disposed on the gate electrode 120 and the second passivation layer 117.

The semiconductor pattern 130 is disposed on the gate insulating layer 125. The semiconductor pattern 130 overlaps the gate electrode 120 and the reflecting pattern 111.

The source electrode 131 is disposed on the gate insulating layer 125. The source electrode 131 overlaps a first end portion of the semiconductor pattern 130. The drain electrode 133 is spaced apart from the source electrode 131. The drain electrode 133 is disposed on the gate insulating layer 125. The drain electrode 133 overlaps a second end portion of the semiconductor pattern 130 opposite to the first end portion. Although, the thin film transistor has a bottom gate structure which includes the gate electrode disposed under the semiconductor pattern in the illustrated exemplary embodiment, the invention is not limited thereto. Alternatively, the thin film transistor may have a top gate structure which includes the gate electrode disposed on (e.g., above) the semiconductor pattern.

The inorganic insulating layer 135 is disposed on the source electrode 131, the drain electrode 133 and the first base substrate 110. The inorganic insulating layer 135 may include a same material as a material of the gate insulating layer 125.

The color filter pattern 160 is disposed on the inorganic insulating layer 135. The color filter pattern 160 may overlap the opening portion OA. In addition, the color filter pattern 160 may partially overlap the non-opening portion NOA. In one exemplary embodiment, for example, the color filter pattern 160 may include one or more color filters such as a red filter, a blue filter and a green filter. An opening may be defined in the color filter pattern 160.

The organic insulating layer 140 is disposed on the color filter pattern 160. The organic insulating layer 140 may include a substantially flat upper surface. A portion of the organic insulating layer 140 may be disposed in the opening defined in the color filter pattern 160.

A contact hole CNT is defined in the organic insulating layer 140 in the organic insulating layer 140 and the inorganic insulating layer 135. The pixel electrode 150 overlaps the opening portion OA. The pixel electrode 150 is physically and/or electrically connected to the drain electrode 133 through the contact hole CNT passing through the organic insulating layer 140 and the inorganic insulating layer 135. An end portion of the pixel electrode 150 partially overlaps the non-opening portion NOA. The pixel electrode 150 may be spaced apart from the color filter layer 160 by a portion of the organic insulating layer 140.

The opposite substrate 200 includes a second base substrate 210, a light blocking pattern 220 and a common electrode 240.

The second base substrate 210 includes a transparent insulating material.

The light blocking pattern 220 corresponds to the non-opening portion NOA. The light blocking pattern 220 is disposed on the second base substrate 210. The light blocking pattern 220 blocks the light at the boundary portion of the pixel areas. In one exemplary embodiment, for example, the light blocking pattern 220 may overlap a data line, a gate line and the thin film transistor. Where the color filter pattern 160 is shown disposed in the array substrate 100, the invention is not limited thereto. In an alternative exemplary embodiment, the opposite substrate may include the color filter pattern 160 disposed on the light blocking pattern 220.

The common electrode 240 is disposed on the light blocking pattern 220 and the second base substrate 210. The common electrode 240 includes a transparent and conductive material.

The backlight unit 700 provides the light to the array substrate 100 of the liquid crystal display panel 500.

According to the array substrate 100 and the liquid crystal display panel 500 of the illustrated exemplary embodiment, the light emitted from the backlight unit 700 is reflected by the reflecting pattern 111 repeatedly so that an efficiency of the light may be improved. In addition, the reflecting pattern 111 is spaced apart from the thin film transistor by the first passivation layer 115 so that an undesirable electric effect to a thin film transistor by the reflecting pattern 111 may be decreased.

The foregoing is illustrative of the invention and is not to be construed as limiting thereof. Although a few exemplary embodiments of the invention have been described, those skilled in the art will readily appreciate that many modifications are possible in the exemplary embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of the invention and is not to be construed as limited to the specific exemplary embodiments disclosed, and that modifications to the disclosed exemplary embodiments, as well as other exemplary embodiments, are intended to be included within the scope of the appended claims. The invention is defined by the following claims, with equivalents of the claims to be included therein.

What is claimed is:

1. An array substrate comprising:
a reflecting pattern on a substrate;
a protecting pattern on the reflecting pattern and overlapping the reflecting pattern;
a first passivation layer covering the substrate and the protecting pattern; and
a thin film transistor on the first passivation layer and overlapping the reflecting pattern,
wherein the first passivation layer comprises silicon oxycarbide.

2. The array substrate of claim 1, further comprising a second passivation layer between the first passivation layer and the thin film transistor,
wherein the second passivation layer comprises inorganic silicon.

3. The array substrate of claim 2, wherein the inorganic silicon comprises silicon oxide or silicon nitride.

4. The array substrate of claim 1, wherein a thickness of the first passivation layer is equal to or greater than about 1 micrometer.

5. The array substrate of claim 1, wherein the reflecting pattern comprises aluminum (Al), gold (Au), silver (Ag), copper (Cu), chromium (Cr), iron (Fe), nickel (Ni) or an alloy thereof.

6. The array substrate of claim 1, wherein the protecting pattern comprises titanium (Ti).

7. The array substrate of claim 1, wherein the thin film transistor comprises:
a gate electrode;
a semiconductor pattern overlapping the gate electrode;
a source electrode overlapping a first end portion of the semiconductor pattern; and
a drain electrode spaced apart from the source electrode and overlapping a second end portion of the semiconductor pattern opposite to the first end portion.

8. The array substrate of claim 1, wherein a boundary portion of the thin film transistor corresponds to a boundary portion of the reflecting pattern.

9. The array substrate of claim 1, further comprising a color filter pattern on the thin film transistor.

10. The array substrate of claim 1, further comprising:
an organic insulating layer on the thin film transistor; and
a pixel electrode on the organic insulating layer.

11. A liquid crystal display panel comprising:
an array substrate comprising a thin film transistor;
an opposite substrate facing the array substrate; and
a liquid crystal layer between the array substrate and the opposite substrate,
wherein the array substrate further comprises:
a reflecting pattern on a base substrate and overlapping the thin film transistor;
a protecting pattern on the reflecting pattern and overlapping the reflecting pattern; and
a first passivation layer covering the base substrate and the reflecting pattern,
wherein
the thin film transistor is on the first passivation layer, and
the first passivation layer comprises silicon oxycarbide.

12. The liquid crystal display panel of claim 11, wherein
the array substrate further comprises a second passivation layer between the first passivation layer and the thin film transistor, and
the second passivation layer comprises inorganic silicon.

13. The liquid crystal display panel of claim 12, wherein the inorganic silicon comprises silicon oxide or silicon nitride.

14. The liquid crystal display panel of claim 11, wherein the reflecting pattern comprises aluminum (Al), gold (Au), silver (Ag), copper (Cu), chromium (Cr), iron (Fe), nickel (Ni) or an alloy thereof.

15. The liquid crystal display panel of claim 11, wherein the protecting pattern comprises titanium (Ti).

16. The liquid crystal display panel of claim 11, wherein the opposite substrate comprises a light blocking pattern corresponding to the reflecting pattern of the array substrate.

17. The liquid crystal display panel of claim 16, wherein the opposite substrate further comprises a color filter pattern disposed on the light blocking pattern.

18. The liquid crystal display panel of claim 16, wherein the opposite substrate further comprises a common electrode on the light blocking pattern.

19. The liquid crystal display panel of claim 11, wherein the array substrate further comprises a color filter pattern on the thin film transistor.

20. The liquid crystal display panel of claim 11, wherein a thickness of the first passivation layer is greater than a thickness of the reflecting pattern.
